(19) United States
(12) Patent Application Publication
(10) Pub. No.: US 2022/0372624 A1
(43) Pub. Date: Nov. 24, 2022

(54) CONTROL APPARATUS AND CONTROL METHOD FOR FILM FORMING APPARATUS

(71) Applicant: Tokyo Electron Limited, Tokyo (JP)

(72) Inventors: Yohei MATSUMOTO, Iwate (JP); Naohide ITO, Iwate (JP); Takehiro FUKADA, Iwate (JP); Shinji ASARI, Iwate (JP)

(21) Appl. No.: 17/747,326

(22) Filed: May 18, 2022

(30) Foreign Application Priority Data
May 21, 2021 (JP) 2021-085977

(51) Int. Cl. C23C 16/52; C23C 16/455; C23C 16/458

(52) U.S. Cl. CPC C23C 16/52; C23C 16/45544; C23C 16/4584

(57) ABSTRACT

A control apparatus is included in a film forming apparatus that includes: a rotation table disposed in a vacuum container and configured to rotate around a central shaft of a table surface, thereby revolving a substrate on a disposing surface provided on a part of the table surface; a stage configured to rotate around the central shaft of the disposing surface, thereby rotating the substrate on the disposing surface; and a gas supply unit configured to supply a gas into the vacuum container. The control apparatus includes: a display control unit configured to display a setting screen for setting a first parameter that controls a rotation of the substrate; and a process execution unit configured to form a film on the substrate while controlling the rotation of the substrate based on the set first parameter.

### CROSS-REFERENCE TO RELATED APPLICATION

This application is based on and claims priority from Japanese Patent Application No. 2021-085977 filed on May 21, 2021 with the Japan Patent Office, the disclosure of which is incorporated herein in its entirety by reference.

### TECHNICAL FIELD

The present disclosure relates to a control apparatus and a control method for a film forming apparatus.

### BACKGROUND

Japanese Patent Laid-Open Publication No. 2016-092156 discloses a film forming apparatus including a rotation mechanism that rotates a disposing region of a substrate on a rotation table so that the substrate rotates while revolving the substrate disposed on the rotation table, and proposes forming a film on the substrate that repeatedly passes through a gas supply region by the revolution.

### SUMMARY

According to an aspect of the present disclosure, a control apparatus is included in a film forming apparatus that includes: a rotation table disposed in a vacuum container and configured to rotate around a central shaft of a table surface, thereby revolving a substrate on a disposing surface provided on a part of the table surface; a stage configured to rotate around the central shaft of the disposing surface, thereby rotating the substrate on the disposing surface; and a gas supply unit configured to supply a gas into the vacuum container. The control apparatus includes: a display control unit configured to display a setting screen for setting a first parameter that controls a rotation of the substrate; and a process execution unit configured to form a film on the substrate while controlling the rotation of the substrate based on the set first parameter.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a vertical cross-sectional side view illustrating an example of a film forming apparatus according to an embodiment.

FIG. 2 is a cross-sectional plan view illustrating an example of the film forming apparatus according to the embodiment.

FIG. 3 is a perspective view illustrating the inside of the film forming apparatus according to the embodiment.

FIG. 4 is a perspective view of a surface of a rotation table of the film forming apparatus according to the embodiment.

FIG. 5 is a view illustrating an example of a hardware configuration of a control apparatus according to the embodiment.

FIG. 6 is a view illustrating an example of a functional configuration of the control apparatus according to the embodiment.

FIG. 7 is a view illustrating an example of a recipe according to the embodiment.

FIG. 8 is a view illustrating an example of a setting screen for setting a first parameter according to the embodiment.

FIG. 9 is a flow chart illustrating an example of a parameter setting process according to the embodiment.

FIG. 10 is a flow chart illustrating an example of a control method of the film forming apparatus according to the embodiment.

FIG. 11 is a flow chart illustrating an example of a control method of the film forming apparatus according to the embodiment.

FIG. 12 is a view illustrating the control method of FIG. 10.

FIGS. 13A to 13C are views illustrating the control method of FIG. 10.

FIG. 14 is a view illustrating the control method of FIG. 10.

FIG. 15 is a view illustrating an example of a setting screen for setting a first parameter at the time of maintenance according to the embodiment.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for implementing the present disclosure will be described with reference to the accompanying drawings. In each of the drawings, the same components may be designated by the same reference numerals and duplicate descriptions thereof may be omitted.

[Film Forming Apparatus]

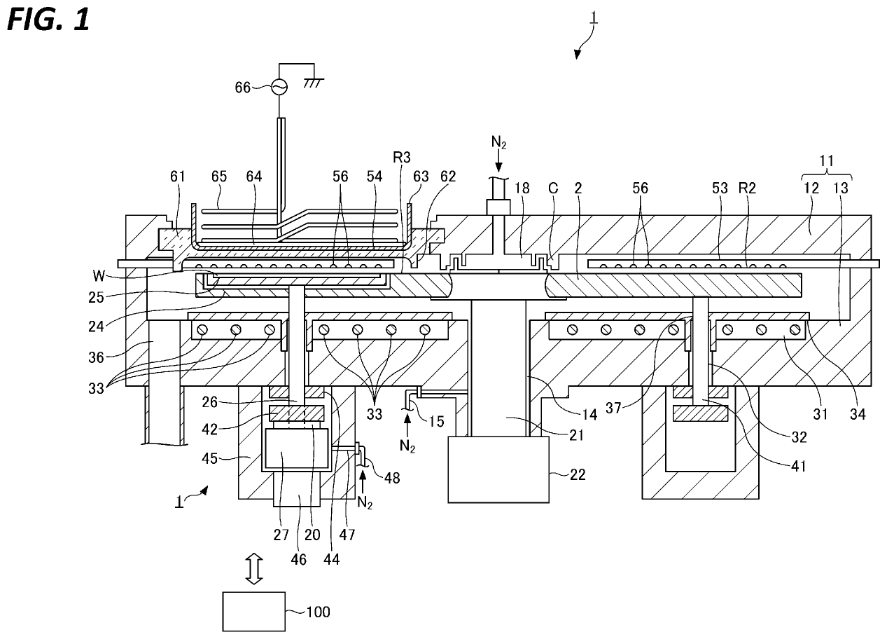

A film forming apparatus 1 according to an embodiment of the present disclosure will be described with reference to FIG. 1. The film forming apparatus 1 forms a film on a wafer W, which is an example of a substrate, by an atomic layer deposition (ALD). The film forming apparatus 1 adsorbs bis(tertiary-butylamino)silane (BTBAS) gas as a raw material gas which is a processing gas containing silicon (Si) on the wafer W. Ozone (O₃) gas serving as an oxidation gas that oxidizes the adsorbed BTBAS gas is supplied to form a molecular layer of silicon oxide (SiO₂), and the molecular layer is exposed to plasma generated from a plasma generation gas in order to modify the molecular layer. The series of processes is repeated a plurality of times to form a SiO₂ film.

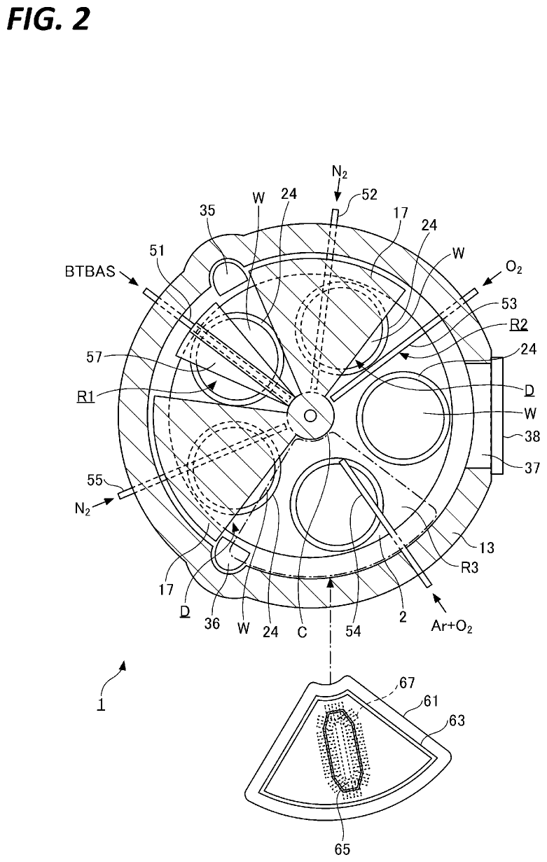

FIGS. 1 and 2 are a vertical cross-sectional side view and a cross-sectional plan view of the film forming apparatus 1, respectively. The film forming apparatus 1 includes a flat vacuum container 11 having a substantially circular shape, and a disk-shaped horizontal rotation table 2 provided in the vacuum container 11. The vacuum container 11 is composed of a top plate 12 and a container body 13 that forms a side wall and a bottom of the vacuum container 11.

A central shaft 21 is provided to extend vertically downward from the center of the rotation table 2. The central shaft 21 is connected to a rotation drive unit 22 for revolution provided to close an opening 14 formed at the bottom of the container body 13. The rotation table 2 is supported in the vacuum container 11 via the central shaft 21 and the rotation drive unit 22 for revolution, and rotates clockwise or counterclockwise in a plan view. A gas supply pipe 15 discharges nitrogen (N₂) gas into a gap between the central shaft 21 and the container body 13, thereby suppressing a raw material gas and an oxidation gas from flowing from the front surface to the back surface of the rotation table 2.

Further, on the lower surface of the top plate 12 of the vacuum container 11, a central region forming portion C having a circular shape in a plan view is formed to face the center of the rotation table 2, and two convex portions 17 extending from the central region forming portion C toward the outside of the rotation table 2 and having a substantially fan-shaped planar shape in which the top is cut in an arc shape, as illustrated in FIG. 2, are formed. The central region forming portion C and the convex portions 17 form a ceiling surface lower than the outer regions thereof. A gap between the central region forming portion C and the center of the rotation table 2 constitutes a N₂ gas flow path 18 (see, e.g., FIG. 1). During the process of the wafer W, N₂ gas is supplied to the flow path 18 from a gas supply pipe connected to the top plate 12 and is discharged from the flow path 18 toward the entire outer circumference of the rotation table 2. The N₂ gas suppresses the raw material gas and the oxidation gas from coming into contact with each other on the center of the rotation table 2.

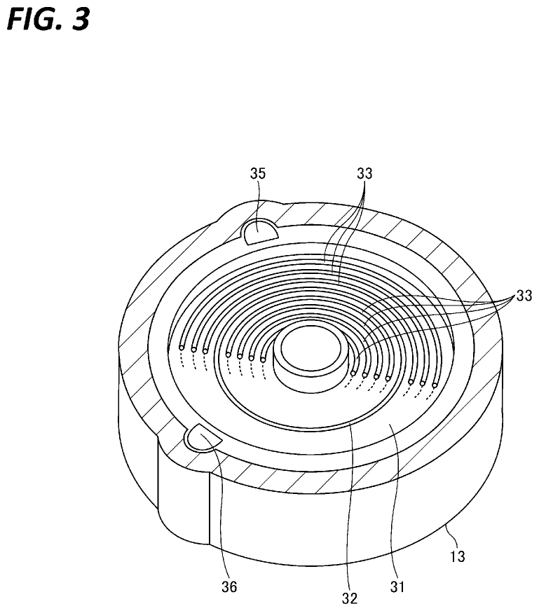

FIG. 3 is a perspective view illustrating an inner bottom surface of the container body 13. The container body 13 is formed with a flat ring-shaped recess 31 below the rotation table 2 along the circumference of the rotation table 2. A ring-shaped slit 32 along the circumferential direction of the recess 31 is opened in the bottom surface of the recess 31, and the slit 32 is formed to penetrate the bottom of the container body 13 in the thickness direction. Heaters 33 for heating the wafer W disposed on the rotation table 2 are disposed in the shape of seven rings on the bottom surface of the recess 31. In FIG. 3, a part of the heater 33 is cut out and illustrated in order to avoid complication.

The heaters 33 are disposed along concentric circles centered on the rotation center of the rotation table 2. Four of the seven heaters 33 are provided inside the slit 32, and the other three are provided outside the slit 32. Further, a shield 34 is provided to cover the upper side of each heater 33 and close the upper side of the recess 31 (see, e.g., FIG. 1). The shield 34 is provided with a ring-shaped slit 37 to overlap the slit 32, and a support column 41 (to be described later) penetrates the slit 37. Further, exhaust ports 35 and 36 for exhausting the inside of the vacuum container 11 are opened outside the recess 31 on the bottom surface of the container body 13. An exhaust mechanism (not illustrated) constituted by a vacuum pump is connected to the exhaust ports 35 and 36.

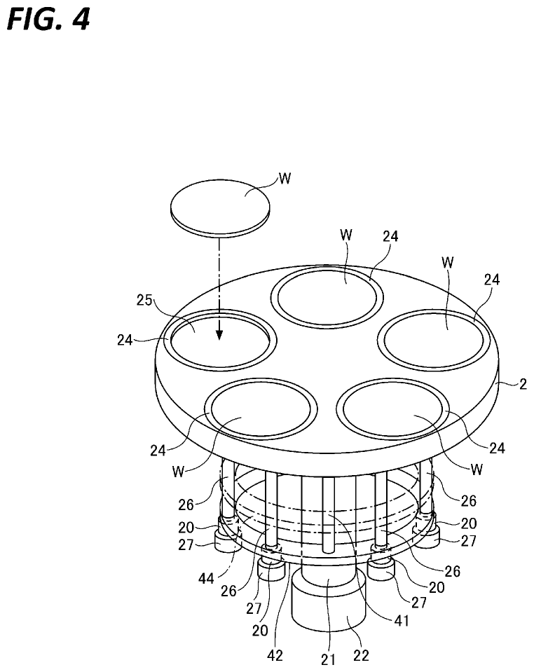

Subsequently, the rotation table 2 will be described with reference to FIG. 4, which illustrates the surface side thereof. Five circular recesses are formed on the surface of the rotation table 2 along the rotation direction of the rotation table 2, and a circular wafer holder 24 is provided in each of the recesses. A recess 25 is formed on the surface of the wafer holder 24, and the wafer W is horizontally accommodated in the recess 25. Therefore, the bottom surface of the recess 25 constitutes a disposing region (disposing surface) on which the wafer is disposed. In this example, the height of the side wall of the recess 25 is the same as the thickness of the wafer W, and is, for example, 1 mm.

For example, three support columns 41 extend vertically downward from positions separated from each other in the circumferential direction of the back surface of the rotation table 2. As illustrated in FIG. 1, each of the support columns 41 penetrates the bottom of the container body 13 through the slit 32 and is connected to a support ring 42 which is a connection portion provided below the container body 13 (see, e.g., FIG. 4). The support ring 42 is formed along the rotation direction of the rotation table 2, is horizontally provided to be suspended from the container main body 13 by the support column 41, and rotates together with the rotation table 2.

Further, a rotation shaft 26, which is a rotation shaft for self-rotation, extends vertically downward from the lower center of the wafer holder 24. The lower end of the rotation shaft 26 penetrates the rotation table 2, penetrates the bottom of the container body 13 through the slit 32, further penetrates the support ring 42 and a magnetic seal unit 20 provided under the support ring 42, and is connected to a rotation drive unit 27 for self-rotation. The magnetic seal unit 20 includes a bearing for rotatably supporting the rotation shaft 26 with respect to the support ring 42, and a magnetic seal (magnetic fluid seal) for sealing a gap around the rotation shaft 26.

The magnetic seal is provided to suppress particles generated from the bearing, for example, lubricating oil used for the bearing from diffusing into a vacuum atmosphere outside the magnetic seal unit 20. Further, since the rotation shaft 26 is supported by the bearing, the wafer holder 24 is in a slightly floating state, for example, from the rotation table 2. The rotation drive unit 27 for self-rotation includes a motor and is provided below the support ring 42 to be supported by the support ring 42 via the magnetic seal unit 20, and the rotation shaft 26 is rotated around the axis by the motor. When the rotation shaft 26 is supported and rotated in this way, the wafer holder 24 is rotated, for example, counterclockwise in a plan view.

The rotation table 2 rotates around a central shaft extending vertically from the center of the table surface, whereby the wafer W on the disposing surface of the wafer holder 24 rotates around the central shaft. The upper surface of the rotation table 2 is a table surface, and the central shaft 21 of the rotation table 2 is an example of a first central shaft extending vertically from the center of the table surface. The wafer holder 24 is an example of a disposing portion, the upper surface of the wafer holder 24 (the bottom surface of the recess 25) is a disposing surface, and the rotation shaft 26 of the wafer holder 24 is an example of a second central shaft that extends vertically from the center of the disposing surface of the disposing portion. The rotation of the wafer W on the disposing surface formed on a part of the table surface around the first central shaft, which is a rotation shaft of the rotation table 2, is also referred to as a revolution of the wafer W or simply a revolution. The rotation of the wafer holder 24 around the second central shaft extending vertically from the center of the disposing surface is also referred to as a self-rotation of the wafer W or simply a self-rotation.

In the film forming apparatus 1, the revolution and the self-rotation are performed in parallel with each other at the time of film formation on the wafer W. The self-rotation of the wafer W includes not only the case where the wafer W continuously rotates around its central shaft, but also the case where the wafer W intermittently rotates around its center. The intermittent rotation also includes the case where the rotation of the wafer W is stopped before rotating around the center one or more times, and then the rotation of the wafer W is restarted.

In FIG. 4, a shield ring 44 is indicated by a chain line. As illustrated in FIG. 1, the shield ring 44 is provided to close the slit of the container body 13 from the lower side of the container body 13, and is configured to rotate together with the rotation table 2. Therefore, the rotation shaft 26 and the support column 41 are provided to penetrate the shield ring 44. The shield ring 44 serves as a heat shield plate for suppressing the rotation drive unit 27 for self-rotation from being exposed to each gas and being excessively heated.

As illustrated in FIG. 1, a lower wall 45 which is formed in a concave shape when viewed in cross section and surrounds the support ring 42, the rotation drive unit 27 for self-rotation, and the shield ring 44 is provided in a ring shape below the container body 13 along the rotation direction of the rotation table 2. Further, five charging mechanisms 46 (FIG. 1 illustrates only one charging mechanism) are provided apart from each other in the circumferential direction on the bottom of the lower wall 45. When the wafer W is not processed, the rotation table 2 is stopped so that the rotation drive unit 27 for self-rotation is located directly under the charging mechanism 46, and each charging mechanism 46 is disposed so that each rotation drive unit 27 for self-rotation may be charged by non-contact power supply from the charging mechanism 46. A gas supply path 47 opens in a space surrounded by the lower wall 45. There is a gas nozzle 48, and N₂ gas is supplied to the space surrounded by the lower wall 45 via the gas supply path 47, for example, during the process of the wafer W, whereby the space is purged. Although not illustrated in FIG. 1, the space communicates with an exhaust path connecting the exhaust ports 36 and 37 and the above-mentioned exhaust mechanism (not illustrated) as illustrated later as an example, and even when particles are generated in the space, the particles are purged to the exhaust path by the N₂ gas and removed.

A transfer port 37 of the wafer W and a gate valve 38 for opening and closing the transfer port 37 are provided on the side wall of the container body 13 (see, e.g., FIG. 2), and the wafer W is delivered between a transfer mechanism that has entered the vacuum container 11 through the transfer port 37 and the recess 25. Specifically, the bottom surface of the recess 25, the bottom of the container body 13, and the rotation table 2 are configured such that through holes are formed at positions corresponding to each other and the tip of a pin moves up and down between the top of the recess 25 and the bottom of the container body 13 through each of the through holes. The wafer W is delivered via the pin. The pin and the through hole of each part through which the pin penetrates are not illustrated.

As illustrated in FIG. 2, a raw material gas nozzle 51, a separation gas nozzle 52, an oxidation gas nozzle 53, a plasma generation gas nozzle 54, and a separation gas nozzle 55 are disposed on the rotation table 2 at intervals in this order in the rotation direction of the rotation table 2. Each of the gas nozzles 51 to 55 is formed in a rod shape extending horizontally along the diameter of the rotation table 2 from the side wall of the vacuum container 11 toward the center, and discharges gas downward from multiple discharge ports formed along the diameter. Each of the gas nozzles 51 to 55 is an example of a gas supply unit that supplies gas into the vacuum container 11.

The raw material gas nozzle 51, which constitutes a processing gas supply mechanism, discharges the above-mentioned bis(tertiary-butylamino)silane (BTBAS) gas. A nozzle cover 57 covers the raw material gas nozzle 51 and is formed in a fan shape that spreads from the raw material gas nozzle 51 toward the upstream and the downstream in the rotation direction of the rotation table 2, respectively. The nozzle cover 57 has a role of increasing the concentration of the BTBAS gas below the nozzle cover 57 and increasing the adsorptivity of the BTBAS gas to the wafer W. Further, the oxidation gas nozzle 53 discharges the ozone gas. The separation gas nozzles 52 and 55 discharge N₂ gas, and are disposed to divide the fan-shaped convex portions 17 of the top plate 12 in the circumferential direction.

The plasma generation gas nozzle 54 discharges a plasma generation gas including, for example, a mixed gas of argon (Ar) gas and oxygen (O₂) gas. The top plate 12 is provided with a fan-shaped opening along the rotation direction of the rotation table 2, and a cup-shaped plasma forming portion 61 (see, e.g., FIG. 1), which includes a dielectric such as quartz and corresponds to the shape of the opening, is provided to close the opening. The plasma forming portion 61 is provided between the oxidation gas nozzle 53 and a protrusion 14 when viewed in the rotation direction of the rotation table 2. In FIG. 2, a position where the plasma forming portion 61 is provided is indicated by a chain line. A ridge portion 62 is provided on the lower surface of the plasma forming portion 61 along the periphery of the plasma forming portion 61. The tip of the plasma generation gas nozzle 54 penetrates the ridge portion 62 from the outer periphery of the rotation table 2 so that gas may be discharged into a region surrounded by the ridge portion 62. The entry of N₂ gas, ozone gas and BTBAS gas below the ridge portion 62 and the plasma forming portion 61 is suppressed, and the decrease in the concentration of the plasma generation gas is suppressed.

A recess is formed on the upper side of the plasma forming portion 61, and a box-shaped Faraday shield 63 that opens upward is disposed in the recess. An antenna 65 in which a metal wire is wound in a coil shape around a vertical axis via an insulating plate member 64 is provided on the bottom surface of the Faraday shield 63, and a radio-frequency power supply 66 is connected to the antenna 65. The bottom surface of the Faraday shield 63 is formed with slits 67 for suppressing the electric field component of the electromagnetic field generated in the antenna 65 from going downward when a radio frequency is applied to the antenna 65 and for directing the magnetic field component downward. The slits 67 extend in a direction orthogonal to (intersecting) the winding direction of the antenna 65, and are formed in large numbers along the winding direction of the antenna 65. By configuring each part in this way, when the radio-frequency power supply 66 is turned on and a radio frequency is applied to the antenna 65, the plasma generation gas supplied below the plasma forming portion 61 may be formed into plasma.

On the rotation table 2, a lower region of the nozzle cover 57 of the raw material gas nozzle 51 is defined as an adsorption region R1 where the BTBAS gas serving as a raw material gas is adsorbed, and a lower region of the oxidation gas nozzle 53 is defined as an oxidation region R2 where the BTBAS gas is oxidized by ozone gas. Further, a lower region of the plasma forming portion 61 is defined as a plasma forming region R3 where the SiO₂ film is modified by plasma. In a lower region of the convex portion 17, the adsorption region R1 and the oxidation region R2 are separated from each other by the N₂ gas discharged from the separation gas nozzles 52 and 55 to form separation regions D and D for suppressing mixing of the raw material gas and the oxidation gas.

The exhaust port 35 is opened outwardly between the adsorption region R1 and the separation region D adjacent to the downstream in the rotational direction with respect to the adsorption region R1, and exhausts excess BTBAS gas. The exhaust port 36 is opened outwardly near a boundary between the plasma forming region R3 and the separation region D adjacent to the downstream in the rotational direction with respect to the plasma forming region R3, and exhausts excess O₃ gas and plasma generation gas. The exhaust ports 35 and 36 also exhaust N₂ gas supplied from each of the separation regions D, the gas supply pipe 15 below the rotation table 2, and the central region forming portion C of the rotation table 2.

The film forming apparatus 1 is provided with a control apparatus 100 (see, e.g., FIG. 1) including a computer for controlling an entire operation of the apparatus. The control apparatus 100 stores a program for executing a film forming process as described later. The program transmits a control signal to each part of the film forming apparatus 1 to control the operation of each part. Specifically, a gas supply amount from each of the gas nozzles 51 to 56, a temperature of the wafer W by the heater 33, a supply amount of N₂ gas from the gas supply pipe 15 and the central region forming portion C, a rotation speed of the rotation table 2, and a rotation speed of the wafer holder 24 are controlled according to the control signal. In the above-mentioned program, a step group is set up so that each process (to be described later) is executed by performing such a control. The program is installed in the control apparatus 100 from a storage medium such as a hard disk, a compact disk, a magneto-optical disk, a memory card, or a flexible disk.

In the film forming apparatus 1, when the rotation table 2 rotates, the wafer W revolves and the film forming process is then performed. As described above, the self-rotation of the wafer W is performed by the rotation of the wafer holder 24 in parallel with the rotation of the rotation table 2, but the rotation of the rotation table 2 and the rotation of the wafer holder 24 are not synchronized with each other. However, the rotation of the rotation table 2 and the rotation of the wafer holder 24 may be synchronized with each other. Specifically, when the rotation table 2 rotates once in a state oriented in a first direction at a predetermined position in the vacuum container 11 and is located at the predetermined position again, the wafer W may rotate at a rotation speed (self-rotation speed) such that the wafer W is oriented in a second direction different from the first direction. The rotation speed (unit: rpm) of the wafer W is set by the control apparatus 100 based on parameters which are set by an operator from a specific setting screen as described later.

[Control Apparatus]

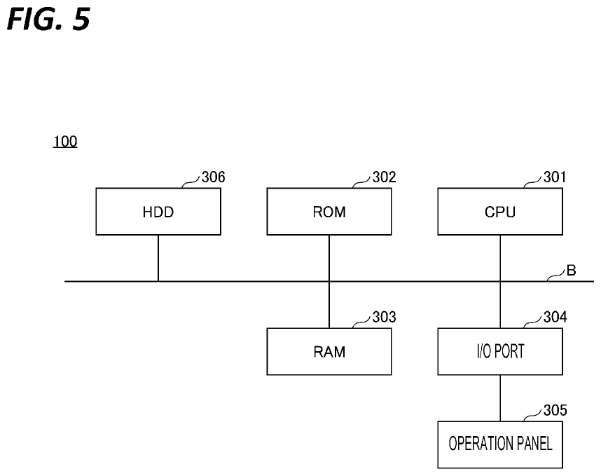

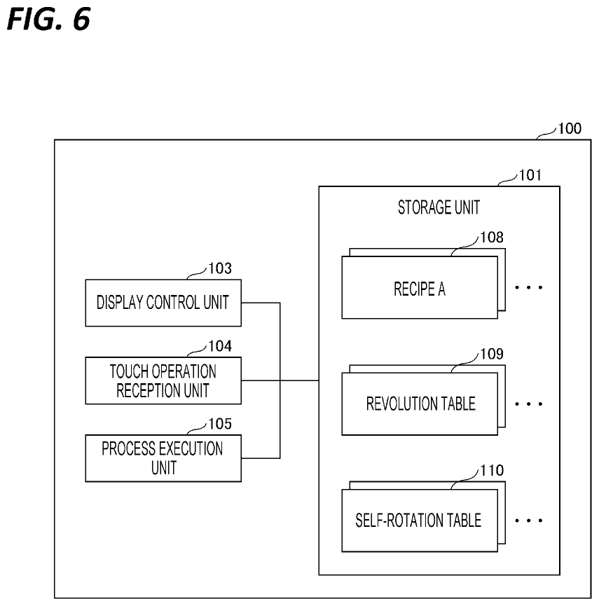

Next, an example of a hardware configuration and a functional configuration of the control apparatus 100 according to the embodiment will be described with reference to FIGS. 5 and 6. As illustrated in FIG. 5, the control apparatus 100 includes a central processing unit (CPU) 301, a read only memory (ROM) 302, a random access memory (RAM) 303, an I/O port 304, an operation panel 305, and a hard disk drive (HDD) 306. Respective units are connected by a bus B.

The CPU 301 controls the operation of the control apparatus 100 based on a program stored in a storage device such as the HDD 306, and a recipe for performing a parameter setting process and a film forming process. For example, the program includes a program that executes a control method of the film forming apparatus. The CPU 301 controls the film forming process of the wafer W disposed on the rotation table 2 based on the recipe.

The ROM 302 is a storage medium that is constituted by an electrically erasable programmable read-only memory (EEPROM), a flash memory, or a hard disk, and stores a program or recipe of the CPU 301. The RAM 303 functions as a work area of the CPU 301.

The I/O port 304 acquires the values of various sensors for detecting a temperature, a pressure, and a gas flow rate from various sensors attached to the plasma processing apparatus 1 and transmits the values to the CPU 301. Further, the I/O port 304 outputs a control signal output by the CPU 301 to the respective units of the film forming apparatus 2 (a rotation table 2, a vacuum pump 640, etc.). The I/O port 304 is connected to an operation panel 305 with which an operator operates the film forming apparatus 1.

The HDD 306 is an auxiliary storage device and may store a recipe serving as information that defines the procedure of the film forming process, and a program that executes a control method of the rotation table in the idle time.

As illustrated in FIG. 6, the control apparatus 100 includes a storage unit 101, a display control unit 103, a touch operation reception unit 104, and a process execution unit 105 as an example of the functional configuration.

The display control unit 103 displays a setting screen for setting a parameter for controlling the self-rotation of the wafer W (hereinafter, referred to as a “first parameter”) on the display operated by the operator. The display control unit 103 causes a setting screen for setting a parameter for controlling the revolution of the wafer W (hereinafter, referred to as a “second parameter”) to be displayed on the operation panel 305 operated by the operator.

The touch operation reception unit 104 receives the information input by the operator's touch operation on the setting screen for setting the first parameter as information of the first parameter, and stores the information in a self-rotation table 110 of the storage unit 101. The touch operation reception unit 104 receives the information input by the operator's touch operation on the setting screen for setting the second parameter as information of the second parameter, and stores the information in a revolution table 109 of the storage unit 101.

The display control unit 103 may display the setting screen of the first parameter according to the type of the wafer W. In this case, the storage unit 101 stores the first parameter received from the setting screen for setting the first parameter according to the type of the wafer W in another self-rotation table 110 for each type of the wafer W.

Accordingly, the first parameter may be easily set for each of a process wafer, a dummy wafer, and a monitor wafer according to the type of wafer. This enables the control of self-rotation according to the type of wafer based on the first parameter. Further, the first parameter may be changed depending on whether the wafer W is disposed on the wafer holder 24. As a result, when the wafer W is disposed on the wafer holder 24 based on the first parameter, the wafer holder 24 is self-rotated, and when the wafer W is not disposed on the wafer holder 24, a fine control such as stopping the rotation of the wafer holder 24 may be performed.

Similarly, the display control unit 103 may display the setting screen of the second parameter according to the type of the wafer W. In this case, the storage unit 101 stores the second parameter received from the setting screen for setting the second parameter according to the type of the wafer W in a plurality of revolution tables 109 for each type of the wafer W.

The process execution unit 105 controls the motor of the rotation drive unit 22 for revolution for each step set in the recipe based on the second parameter stored in the revolution table 109, thereby controlling the revolution of the wafer W. The process execution unit 105 controls the motor of the rotation drive unit 27 for self-rotation for each step set in the recipe based on the first parameter stored in the self-rotation table 110, thereby controlling the self-rotation of the wafer W. The process execution unit 105 forms a film on the wafer W by controlling the self-rotation and revolution to satisfy process conditions such as the flow rate and pressure of gas according to the designated recipe.

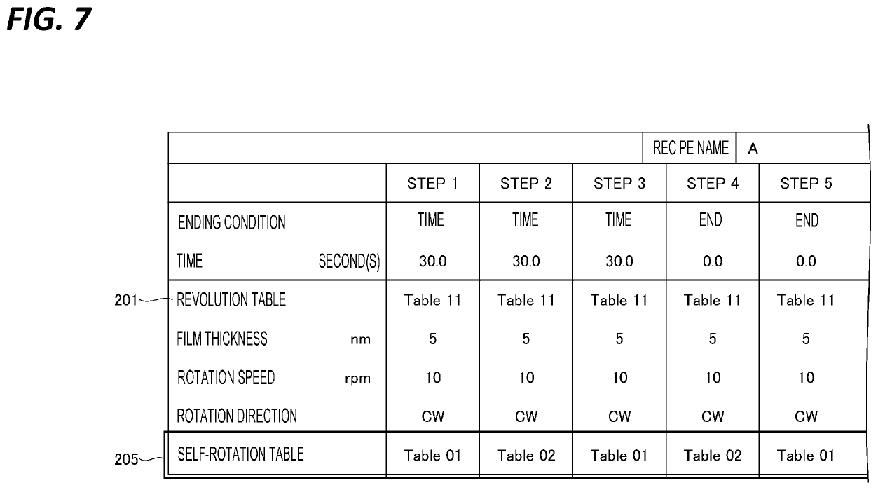

The storage unit 101 stores a plurality of recipes (recipe A, recipe B, . . . ) corresponding to the substrate process executed by the film forming apparatus 1. FIG. 7 is a view illustrating an example of a recipe according to the embodiment. In recipe A, numbers 201 and 205 of the revolution table 109 and the self-rotation table 110 used for each step are displayed along with the process conditions for each step. For example, in step 1, the revolution table “Table 11” and the self-rotation table “Table 01” are designated.

In the case of this example, the process execution unit 105 controls the rotation drive unit 22 for revolution by referring to the second parameter stored in the revolution table “Table 11” according to recipe A, and rotates the rotation table 2 in a predetermined rotation speed and rotation direction. The process execution unit 105 controls the rotation drive unit 27 for self-rotation by referring to the first parameter stored in “Table 01” or “Table 02” set for each step of the self-rotation table, and rotates the wafer holder 24 in the set rotation speed and rotation direction. The process execution unit 105 controls process conditions according to recipe A while the wafer W self-rotates and revolves, and forms a film on the wafer W. Accordingly, the motors of the rotation drive unit 22 for revolution and the rotation drive unit 27 for self-rotation are controlled with reference to the second parameter and the first parameter, respectively. As a result, the rotation table 2 is rotated around the central shaft 21 serving as the first central shaft, and the wafer holder 24 is rotated around the rotation shaft 26 serving as the second central shaft. The process execution unit 105 supplies gas from the gas supply unit (gas nozzles 51 to 55) to the gas supply region in a part of the table surface while controlling such rotations, and forms a film on the wafer W that repeatedly passes through the gas supply region by the revolution. The wafer W that repeatedly passes through the gas supply region self-rotates by rotating the wafer holder 24 while revolving. When the wafer W not only revolves but also self-rotates, the gas is uniformly supplied onto the wafer W, whereby the film may be uniformly formed on the entire surface of the wafer W and the accuracy of film formation may be improved.

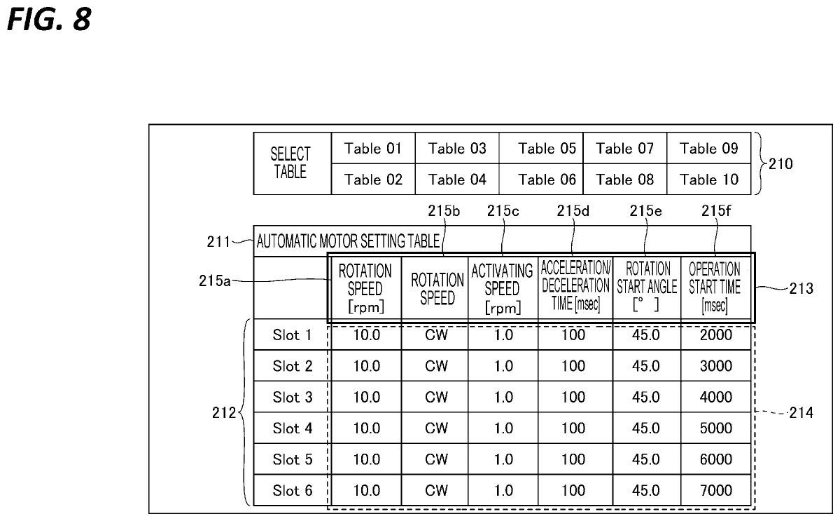

FIG. 8 illustrates an example of a setting screen of a first parameter. The display control unit 103 causes the operation panel 305 to display a setting screen including at least one of first parameters of a rotation speed, a rotation direction, an activating speed, an acceleration/deceleration time, a rotation start angle, and an operation start time when rotating the wafer holder 24. The operator may select a self-rotation table to be used in the process by pressing any button of a display component 210 using the setting screen of FIG. 8.

The operator may set the first parameter for each slot 212 by touching the screen for each item 213 of the first parameter displayed under a display component 211 of a self-rotation motor setting table. The first parameters of each slot 212 are a rotation speed 215a, a rotation direction 215b, an activating speed 215c, an acceleration/deceleration time 215d, a rotation start angle 215e, and an operation start time 215f. However, the first parameter may include at least one of the rotation speed 215a, the rotation direction 215b, the activating speed 215c, the acceleration/deceleration time 215d, the rotation start angle 215e, and the operation start time 215f. The numerical values set in the area 214 of FIG. 8 are first parameter values given for each slot 212 with respect to each item 213 of the first parameters. The slot number is an identification number assigned to each of the plurality of wafer holders 24. In the film forming apparatus 1 illustrated in FIGS. 2 and 4, five wafer holders 24 are provided, but the number is not limited to five, and one or more wafer holders 24 may be provided. In the example of FIG. 8, six wafer holders 24 are provided. Therefore, the first parameter for the wafer holder 24 in slots 1 to 6 is displayed.

The process execution unit 105 performs a rotation control with reference to the first parameter of the self-rotation table set for each step of the recipe of FIG. 7. Thus, the rotation of the wafer holder 24 for each step and the self-rotation of the wafer W may be controlled with reference to the first parameter of the self-rotation table set on the setting screen illustrated in FIG. 8. Since the first parameter is set for each step, a control may be implemented, for example, such that the wafer holder 24 is gradually rotated in step 1 of a recipe and the wafer holder 24 is fully rotated in step 2.

In this way, in the present disclosure, by providing the operator with the setting screen of the first parameter, the first parameter indicating a control procedure of the motor of the rotation drive unit 27 for self-rotation may be easily set for each step of a recipe. Further, since the value of the first parameter for each slot may be set from the setting screen of the first parameter, the wafer holder 24 of each slot may be operated individually. Thus, it is possible to easily set parameters for forming the wafer W while revolving and self-rotating the wafer W disposed on the rotation table 2.

The display control unit 103 may cause the operation panel 305 to display a setting screen including at least one of the rotation speed and the rotation direction when rotating the rotation table 2 on the setting screen of the second parameter, thereby facilitating the setting of the second parameter.

[Parameter Setting Process]

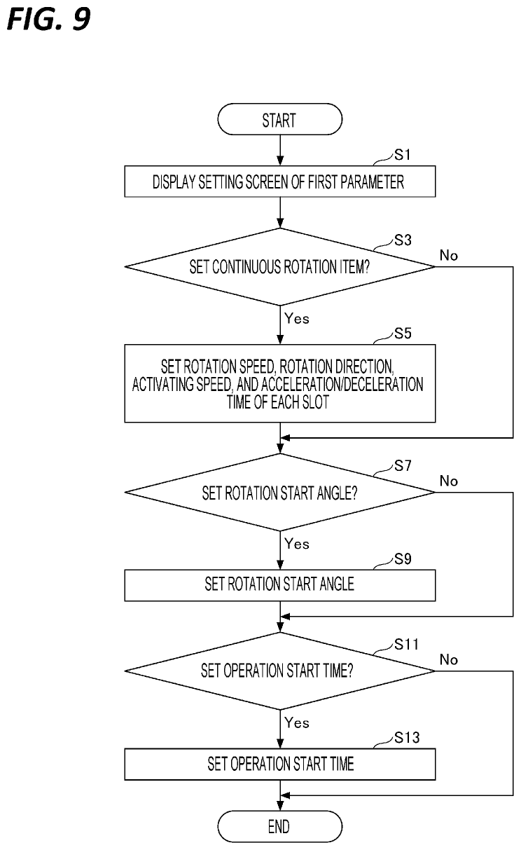

FIG. 9 is a flow chart illustrating an example of a parameter setting process according to the embodiment. When the operator requests the setting of the first parameter, the display control unit 103 displays the setting screen of the first parameter in step S1. As a result, for example, the setting screen of FIG. 8 is displayed.

Next, the touch operation reception unit 104 receives a touch operation on the operation panel 305. When receiving the touch operation of a continuous rotation item by the operator, in step S5, the touch operation reception unit 104 receives an input of at least one of the rotation speed, the rotation direction, the activating speed, and the acceleration/deceleration time of each slot and stores the input in the self-rotation table 110 of the storage unit 101.

When the touch operation reception unit 104 receives a touch operation of the rotation start angle item by the operator, the touch operation reception unit 104 determines in step S7 that the rotation start angle is set. In step S9, the input of the rotation start angle of each slot is received and stored in the self-rotation table 110 of the storage unit 101.

When the touch operation reception unit 104 receives a touch operation of the operation start time by the operator, the touch operation reception unit 104 determines in step S11 that the operation start time is set. In step S13, the input of the operation start time of each slot is received, stored in the self-rotation table 110 of the storage unit 101, and the present process is ended.

When the touch operation reception unit 104 does not detect any touch operation, the present process is ended without setting the first parameter.

[Control Method for Film Forming Apparatus]

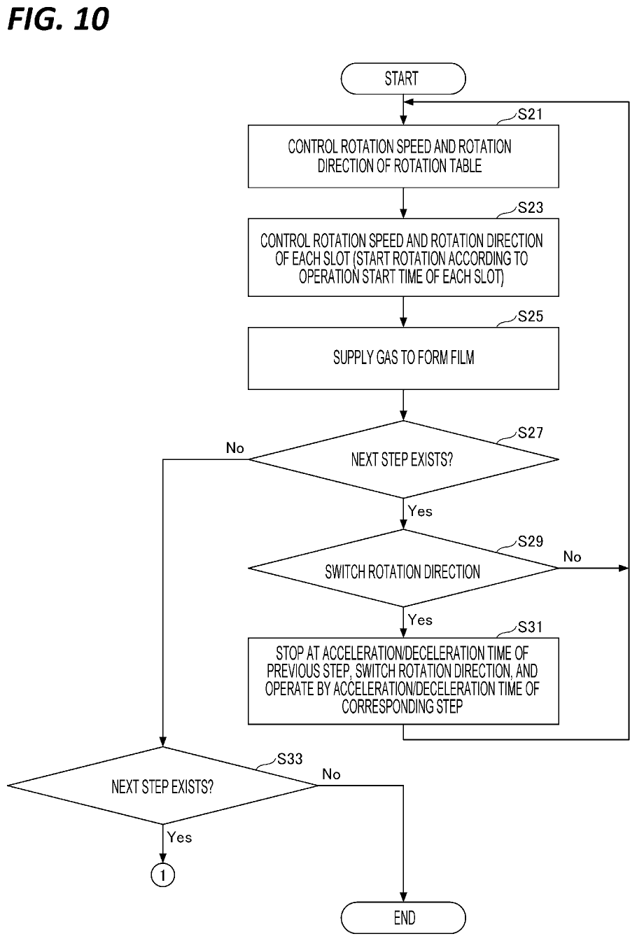

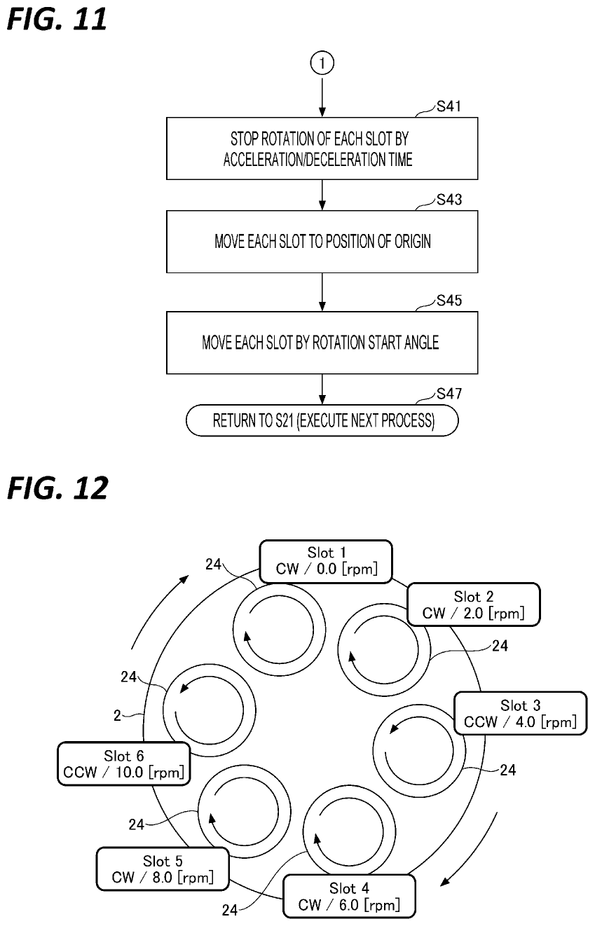

Next, a control method of the film forming apparatus executed by the film forming apparatus 1 using the set first parameter will be described with reference to FIGS. 10 to 14. FIG. 10 is a flow chart illustrating an example of a control method of the film forming apparatus according to the embodiment. FIG. 11 is a flow chart illustrating an example of a control method (process between steps) of the film forming apparatus according to the embodiment. FIGS. 12 to 14 are views illustrating the control method of the present disclosure.

When the present process is started, in step S21, the process execution unit 105 rotates the rotation table 2 around the central shaft 21 extending vertically from the center of the rotation table 2 based on the second parameter set in the revolution table 109 according to the recipe. This controls the revolution of the wafer W. The rotation speed and the rotation direction (clockwise or counterclockwise in a plan view) of the rotation table 2 are controlled based on, for example, the second parameter.

In step S23, the process execution unit 105 rotates the wafer holder 24 around the rotation shaft 26 extending vertically from the center of the wafer holder 24 based on the first parameter set in the self-rotation table 110 for each step according to the recipe. This controls the self-rotation of the wafer W. The process execution unit 105 controls the rotation speed and the rotation direction of the wafer holder 24 based on, for example, the first parameter. In addition, the process execution unit 105 may control at least one of the activating speed, acceleration/deceleration time, rotation start angle, and operation start time based on the first parameter. A control method of the parameters of the activating speed, acceleration/deceleration time, rotation start angle, and operation start time will be described later. Although steps S21 and S23 have been described separately for convenience, these steps may be executed simultaneously or in parallel.

Next, in step S25, the process execution unit 105 supplies a desired gas from the gas nozzles 51 to 55 to the vacuum container 11, and forms the wafer W on the wafer holder 24. In step S27, the process execution unit 105 determines whether there is a next step, and when it is determined that there is a next step, the process execution unit 105 determines in step S29 whether to switch the rotation direction. When it is determined that the rotation direction is to be switched, in step S31, the process execution unit 105 decelerates the rotation of the wafer holder 24 with the acceleration/deceleration time set in the first parameter of the previous step, stops, switches the rotation direction, and accelerates the rotation of the wafer holder 24 with the acceleration/deceleration time of the step, and the process returns to step S21. When it is determined in step S29 that the rotation direction is not to be switched, the process returns to step S21 as it is. When it is determined in step S27 that there is no next step, the process execution unit 105 determines in step S33 whether there is a next process. When it is determined that there is no next process, the present process ends.

When it is determined that there is a next process, the process proceeds to step S41 in FIG. 11, and the process execution unit 105 stops the rotation of the wafer holder 24 in each slot with the acceleration/deceleration time.

In step S43, the process execution unit 105 moves the wafer holder 24 of each slot to the position of the origin. In step S45, the process execution unit 105 moves (rotates) the wafer holder 24 of each slot by the rotation start angle from the position of the origin, and in step S47, the process returns to step S21, and the next process is executed by performing the processes after step S21. In the present disclosure, an example has been given in which each step in FIG. 11 is performed every time the process changes, but when a single process is composed of a plurality of steps, each step in FIG. 11 may be performed every time the step changes. Further, each step in FIG. 11 may be performed when a specific step among a plurality of steps included in a single process is started.

FIG. 12 illustrates an example of the self-rotation of the six wafer holders 24 indicated in slots 1 to 6 and the revolution of the rotation table 2 by performing the processes of steps S21 and S23. In the control method according to the present embodiment, the rotation of the six wafer holders 24 is controlled according to the rotation speed and the rotation direction arbitrarily set for each slot. The switching of the rotation direction may be controlled for each slot by performing the process of step S31.

The wafer holder 24 of the slot whose rotation speed is set to 0 rpm is moved to the origin. Since the movement of the origin is the same as the process of step S45 in FIG. 11, the movement will be described later.

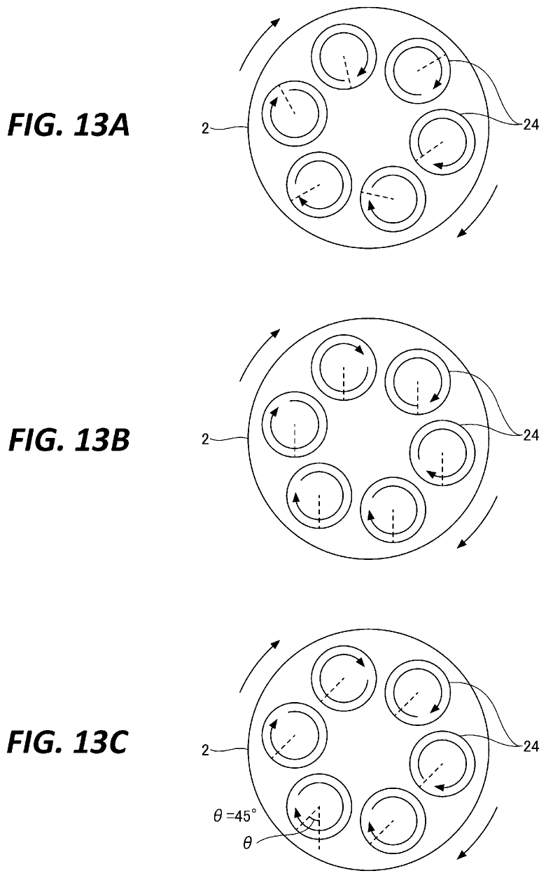

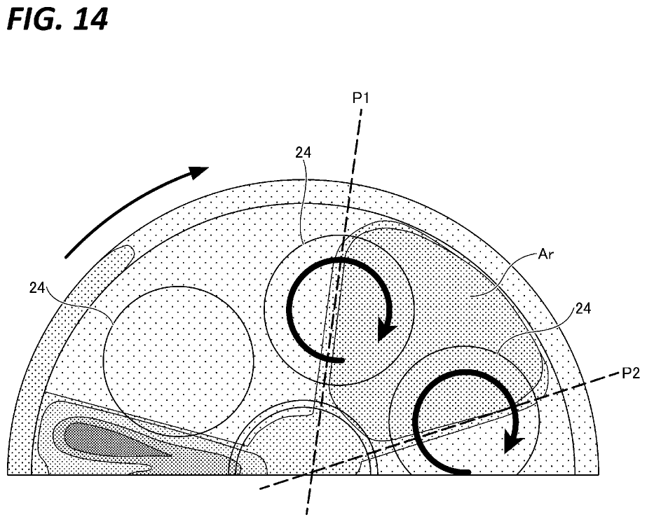

FIG. 13A corresponds to the process of step S41 of FIG. 11, FIG. 13B corresponds to the process of step S43, and FIG. 13C corresponds to the process of step S45. FIG. 13A illustrates a state in which the rotation of the wafer holder 24 of each slot is stopped with the acceleration/deceleration time in the process of step S41 of FIG. 11. At this time, when the origin of each slot is indicated by a broken line, the rotation position (position of the origin) is indefinite.

FIG. 13B illustrates a state in which the origin is moved and stopped at the start of or before the next process in the process of step S43. In this case, the origin is moved and stopped in the acceleration/deceleration time of the previous step. The origin may be moved by photographing a marker attached to the wafer holder 24 of each slot with a camera and adjusting the position of the photographed marker to a predetermined angle indicating the position of the origin.

In FIG. 13C, the wafer holder 24 of each slot is moved to the rotation start angle in the process of step S45. In the example of FIG. 13C, the rotation start angle is set to 45° and the wafer holder 24 is moved. The movement and stoppage of the wafer holder 24 at the rotation start angle are performed in the acceleration/deceleration time of the execution step. It is possible to execute the film forming process after stopping the wafer holders 24 of all slots at a specific angle in this way, thereby further improving the film forming result.

FIG. 14 is a view illustrating an example of a control method that uses the operation start time as the first parameter. For example, in the example of FIG. 8, the operation start times are different in slots 1 to 6. In FIG. 14, the wafer holder 24 of each slot rotates clockwise while gas is being supplied from the gas supply unit (the gas nozzles 51 to 55, the shower head) to a gas supply region Ar in a part of the table surface of the rotation table 2.

The operation start time is set when a delay time is required before the wafer holder 24 starts to rotate. For example, when the rotation table 2 is stopped at an arbitrary revolution position, gas is switched, and then the rotation (revolution) of the rotation table 2 is started at an arbitrary rotation speed and rotation direction, after the operation start time has elapsed from the rotation time, the wafer holder 24 of each slot is rotated (self-rotated). As a result, the self-rotation start time of the wafer holder 24 may be set differently for each slot.

The gas supply region Ar in FIG. 14 is a film forming area and is filled with gas. For each slot, the wafer holder 24 is controlled to self-rotate when starting to pass through the gas supply region Ar. By starting to rotate each slot at a time deviated from the rotation of the rotation table 2 based on the operation start time, the wafer holder 24 of each slot may start to self-rotate at a broken line (center line) P1 that starts to pass through the gas supply region Ar. The operation end time may also be set in the first parameter. In this case, it is also possible to end the self-rotation of the wafer holder 24 in each slot or start the stop operation at a broken line (center line) P2 that has passed through the gas supply region Ar.

[Parameter Setting Process during Maintenance]

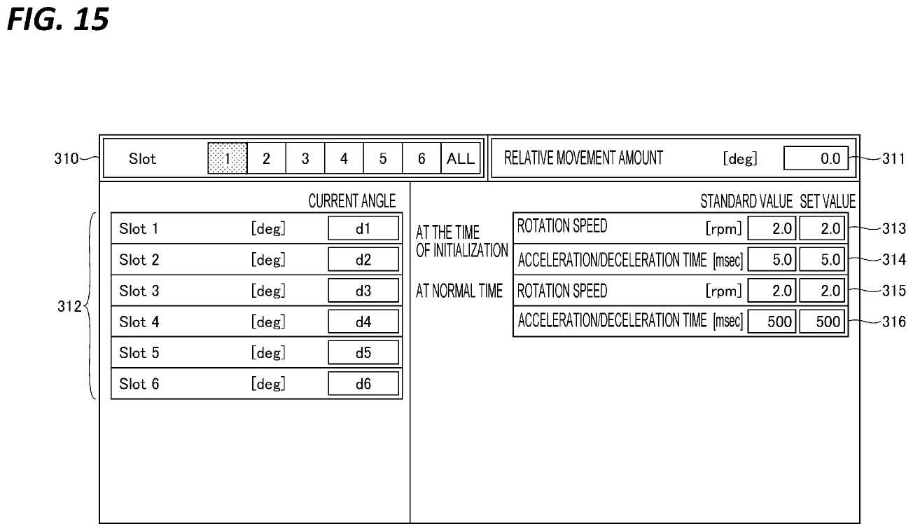

Next, a parameter setting process at the time of maintenance will be described with reference to FIG. 15. FIG. 15 is a view illustrating an example of a setting screen of a first parameter at the time of maintenance according to the embodiment.

When the operator requests the display of the setting screen of the first parameter at the time of maintenance, the display control unit 103 displays a setting screen for maintenance illustrated in FIG. 15. The setting of the first parameter by the setting screen is used when the operator wants to perform maintenance and evaluation experiments while manually controlling the self-rotation of the wafer holder 24 in each slot.

The display component 310 may select the wafer holder 24 of the slot to be operated. The selection includes an individual selection in which each of the wafer holders 24 in slots 1 to 6 may be selected, and a batch selection in which all wafer holders 24 (ALL) may be selected at once.

The display component 312 may set the current angle for indicating the rotation position of the wafer holder 24 of slots 1 to 6. Slots 1 to 6 are set to the current angles d1 to d6, respectively. With the parameter, the origin of slots 1 to 6 may be moved to the angles d1 to d6 at the start of maintenance.

The display components 313 to 316 are set to control the rotation speed of a motor of the rotation drive unit 27 for self-rotation at the time of maintenance. The rotation speed and acceleration/deceleration time at the time of initialization and the rotation speed and acceleration/deceleration time at the normal time may be set.

The display component 311 sets a relative movement amount by an angle in order to set how much the wafer holder 24 of each slot is rotated from the present time.

It is possible to make various settings, such as automatically controlling the rotation speed of the motor of the rotation drive unit 27 for self-rotation according to the rotation speed of the motor of the rotation drive unit 22 for revolution.

Accordingly, by using the setting screen of the first parameter at the time of maintenance, the operating conditions of the wafer holders 24 of slots 1 to 6 may be changed, for example, to cause the wafer holders 24 to operate separately under six different conditions and perform six types of evaluation experiments at once. Such a setting screen may be used not only at the time of development of the film forming apparatus 1 but also at the time of activating the film forming apparatus 1.

As described above, according to the control apparatus and the control method for the film forming apparatus of the present embodiment, it is possible to easily set parameters for forming the film while self-rotating and revolving the substrate disposed on the rotation table. With the control method for the film forming apparatus, it is also possible to perform a control such that the rotation of the wafer holder 24 is stopped at a predetermined timing in order to suppress the wafer W from popping out from the wafer holder 24 in a process having a large gas flow rate.

According to an aspect of the present disclosure, it is possible to easily set parameters for forming a film while self-rotating and revolving a substrate disposed on a rotation table.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A control apparatus for a film forming apparatus including:
a rotation table disposed in a vacuum container and configured to rotate around a first central shaft extending vertically from a center of a table surface, thereby revolving a substrate on a disposing surface provided on a part of the table surface;
a stage configured to rotate around a second central shaft extending vertically from a center of the disposing surface, thereby rotating the substrate on the disposing surface; and
a gas supply configured to supply a gas into the vacuum container,
the control apparatus comprising:
a display controller configured to display a setting screen for setting a first parameter that controls a rotation of the substrate; and
a process executor configured to form a film on the substrate while controlling the rotation of the substrate based on the set first parameter.

2. The control apparatus according to claim 1, wherein the display controller displays the setting screen of the first parameter including at least one of a rotation speed, a rotation direction, an activating speed, an acceleration/deceleration time, a rotation start angle, and an operation start time when rotating the stage.

3. The control apparatus according to claim 2, wherein the display controller displays the setting screen of the first parameter according to a type of the substrate.

4. The control apparatus according to claim 3, wherein the display controller displays a setting screen for setting a second parameter for controlling a revolution of the substrate.

5. The control apparatus according to claim 4, wherein the gas supply supplies the gas to a gas supply region in a part of the table surface, and the process executor is configured to form a film on the substrate that repeatedly passes through the gas supply region by the revolution.

6. The control apparatus according to claim 1, wherein the display controller displays the setting screen of the first parameter according to a type of the substrate.

7. The control apparatus according to claim 1, wherein the display controller displays a setting screen for setting a second parameter for controlling the revolution of the substrate.

8. The control apparatus according to claim 1, wherein the gas supply supplies the gas to a gas supply region in a part of the table surface, and the process executor is configured to form a film on a substrate that repeatedly passes through the gas supply region by the revolution.

9. A control method of a film forming apparatus, the method comprising:
providing a film forming apparatus including:
a rotation table disposed in a vacuum container and configured to rotate around a first central shaft extending vertically from a center of a table surface, thereby revolving a substrate on a disposing surface provided on a part of the table surface;
a stage configured to rotate around a second central shaft extending vertically from a center of the disposing surface, thereby rotating the substrate on the disposing surface; and
a gas supply configured to supply a gas into the vacuum container;
displaying a setting screen for setting a first parameter that controls a rotation of the substrate; and
forming a film on the substrate while controlling the rotation of the substrate based on the first parameter.
